(19) United States
(12) Patent Application Publication
(10) Pub. No.: US 2010/0025811 A1
(43) Pub. Date: Feb. 4, 2010

(54) INTEGRATED CIRCUIT WITH BUILT-IN HEATING CIRCUITRY TO REVERSE OPERATIONAL DEGENERATION

(76) Inventors: Gary Bronner, Los Altos, CA (US); Brent S. Haukness, Monte Sereno, CA (US); Fariborz Assaderaghi, Los Altos, CA (US); Mark D. Kellam, Pittsboro, NC (US); Mark Horowitz, Menlo Park, CA (US)

Correspondence Address: Shemwell / Rambus, P.O. Box 70307, Sunnyvale, CA, 94086, US

(21) Appl. No.: 12/516,499

(22) PCT Filed: Nov. 29, 2007
(86) PCT No.: PCT/US07/85979

§ 371 Date: May 27, 2009

Related U.S. Application Data
(60) Provisional application No. 60/867,704, filed on Nov. 29, 2006.

(51) Int. Cl. H01L 23/34

(52) U.S. Cl. 257/528; 257/E23.081

(57) ABSTRACT

An integrated circuit device (100) includes structures (104) that exhibit performance degradation as a function of use (e.g., accumulated defects within the tunneling oxide of a Flash memory cell, or trapped charge within a charge storage layer) and heating circuitry (101) disposed in proximity to the structures to heat the structures to a temperature that reverses the degradation. The word lines or the bit lines of the memory device are used as heating elements (107).

### CROSS-REFERENCE TO RELATED APPLICATIONS

This application claims priority from, and hereby incorporates by reference, U.S. Provisional Application No. 60/867,704, filed Nov. 29, 2006 and entitled “Integrated Circuit With Built In Heater to Anneal Out Oxide Traps.”

### TECHNICAL FIELD

The disclosure herein relates to reversing operational degeneration within an integrated circuit device.

### BACKGROUND

Operation of integrated circuits can cause damage to insulators (typically but not limited to silicon dioxide) that limit their reliability and product lifetime. For example, oxide trap generation in Flash memory chips limit the number of write erase operations and also limit data retention. In addition, hot electron damage to silicon dioxide (SiO₂) may shift device threshold voltage and cause the device drive current to be reduced which may lead to device mismatch.

### BRIEF DESCRIPTION OF THE DRAWINGS

The disclosure herein is illustrated by way of example, and not by way of limitation, in the figures of the accompanying drawings and in which like reference numerals refer to similar elements and in which:

FIG. 1 illustrates a generalized embodiment of an on-chip (on-die) annealing circuit that may be used to reverse degeneration of oxides or other materials or structures disposed on or within a semiconductor or other type of substrate;

FIGS. 2A-2C illustrate examples of heating elements that may be employed within an integrated circuit device to support on-die annealing operations and that correspond to generalized heating element shown in FIG. 1;

FIGS. 3A-3C illustrate examples of power delivery circuitry that may be provided within or in conjunction with an annealing circuit to power a heating element;

FIGS. 4A and 4B illustrate exemplary arrangements for delivering power to a heating element within an annealing circuit;

FIGS. 5A and 5B illustrate exemplary approaches for achieving desired heating element resistance (or range of resistances) through control of physical characteristics or geometry of the heating element;

FIGS. 6A and 6B illustrate exemplary embodiments for controlling the amount of energy delivered to a heating element and thus controlling the annealing temperature;

FIG. 7 illustrates an embodiment of a mode register (or configuration circuit) optionally provided within an anneal-enabled integrated circuit and that may be programmed in response to host commands (or one-time programmed, for example, during device production) to provide flexible control over triggering and execution of anneal operations;

FIG. 8 illustrates an embodiment of a system that includes one or more anneal-enabled integrated circuits 371₁-371ₙ and an external controller 375, as well as anneal triggering determinations that may be carried out within the external controller and/or anneal-enabled integrated circuits;

FIGS. 9A-9C illustrate biasing of a semiconductor substrate or bulk in a manner that limits or prevents disturbance of stored data, thus permitting data to be retained during anneal operations; and

FIGS. 10, 11A and 11B illustrate particular embodiments of an annealing circuit in accordance with the principles and embodiments of FIGS. 1-9.

### DETAILED DESCRIPTION

### I. Annealing Generally

In various embodiments described herein, heating circuitry is formed on an integrated circuit die to enable the temperature in the locality of insulators or other structures that exhibit progressive degeneration to be raised to a point at which the degeneration or damage is reversed (i.e., reduced or completely eliminated). This temperature-induced restoration or correction is referred to herein as annealing.

In one embodiment, for example, accumulated damage within the tunneling oxides of floating gate cells in a Flash memory device may be reversed in an annealing operation by application of temperatures in the neighborhood of 400° C., a temperature that may be achieved during device operation through conduction of sufficient current (the annealing current) through the word lines, bit lines and/or other structures that form part of (or are disposed in proximity to) the Flash cell array. Similarly, annealing operations may be used to dislodge trapped carriers in an array of SONOS-type (silicon-oxide-nitride-oxide-silicon) storage cells, by delivering an annealing current sufficient to raise the temperature of the nitride-based charge storage elements to approximately 250° C. Similar operation may be carried out for other types of charge-storage layers (e.g., TANOS-type cells having a charge-storage layer formed by Si-Oxide-SiN—Al₂O₃—TaN.) Lower temperatures may be sufficient in both such examples, or higher temperatures may be required. Also, similar operations may be used to reverse degeneration in any use-degraded materials that are susceptible to repair through annealing including, for example and without limitation, oxides in MOSFETs (metal-oxide-semiconductor field effect transistors) or other types of transistors (thus correcting for threshold voltage mismatch and other types of wear that often limits the useful lifetime of such devices). Moreover, by providing a restorative option in the on-die annealing mechanism and control thereof, devices that are typically constrained to lower operational voltages or clock rates to limit device degradation may be freed to operate at higher voltages and/or clock rates, thereby achieving increased performance. That is, by providing on-die circuitry to reverse degeneration, the performance/reliability balance inherent in most semiconductor device specifications may be shifted to higher performance, with occasional or event-driven anneal operations carried out to compensate for the increased degradation rate. Further, in the case of Flash memory and other wear-limited technologies, the ability to reverse degradation through run-time and/or startup-time annealing operations removes wear-based constraints and enables such technologies to be applied in a much larger variety of applications where their low cost-per-bit or other benefits dictate.

### II. Annealing Apparatus/Circuitry

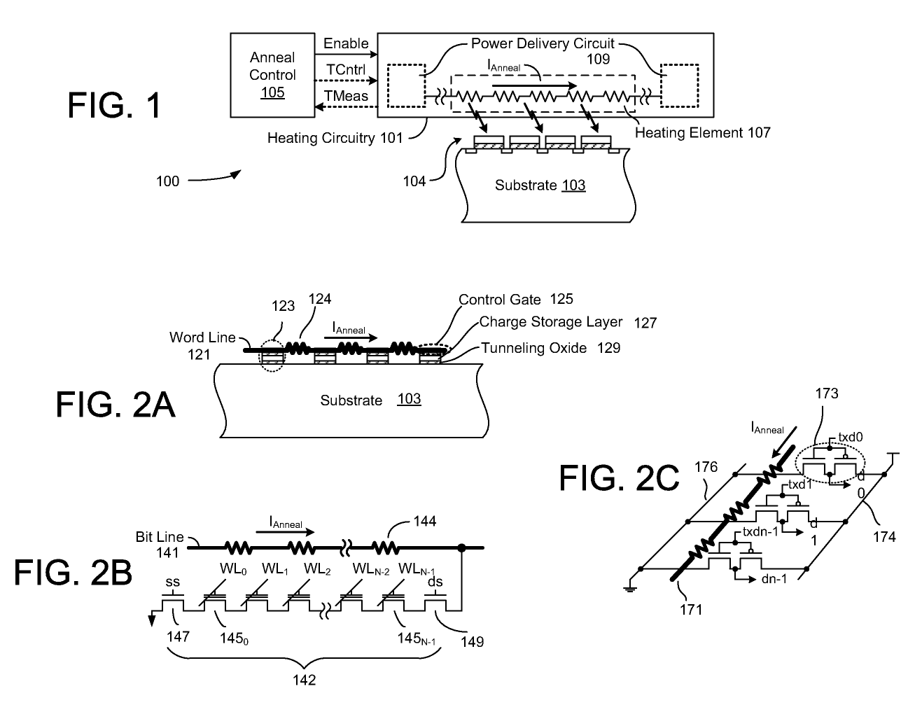

FIG. 1 illustrates a generalized embodiment of an on-chip (on-die) annealing circuit 100 that may be used to reverse degeneration of oxides or other materials or structures 104 disposed on or within a semiconductor or other type of substrate 103. The annealing circuit 100 includes an anneal controller 105 and heating circuitry, with the heating circuitry itself including a resistive heating element 107 and a power delivery circuit 109 for enabling an annealing current, I_{Anneal}, to flow through the heating element 107. Conduction of the annealing current through the heating element 107 raises the temperature of the heating element to a point at which degeneration of structures 104 and/or substrate 103 (defects, carrier traps or other types of degradation) is reversed, thus restoring the use-degraded material to an improved state, in many cases, to virgin or near-virgin condition. As shown, the anneal controller 105 provides an enable signal (Enable) to the heating circuitry 101 to enable annealing operations to be carried out at a desired time, and also may optionally receive a feedback signal (TMeas) indicative of the temperature generated in the annealing operation. The anneal controller 105 may also output a temperature control signal (TCntrl) to establish a desired annealing temperature, referred to herein as the temperature setpoint. All these and other operations of the anneal controller are described below in greater detail, as are examples of specific embodiments of the heating circuitry 101.

A. Heating Element Examples

FIGS. 2A-2C illustrate examples of heating elements that may be employed within an integrated circuit device to support on-die annealing operations and that correspond to generalized heating element 107 of FIG. 1. Referring first to FIG. 2A, the word lines (or control gates) 121 within a cell array (e.g., a storage cell array such as a Flash memory cell array or SONOS (silicon-oxide-nitride-oxide-silicon) array, or any other type of use-degraded semiconductor array having word lines that are used to enable concurrent parallel access to multiple cells) may be used as heating elements by providing power delivery circuitry (described below, but not shown in FIG. 2A) to enable conduction of an annealing current (I_{Anneal}) through the word line 121. In one embodiment, the intrinsic resistance 124 of the word line itself (typically implemented in polysilicon or polycide traces that extend across the width or at least partly across the width of the cell array) establishes the resistance of the heating element so that when a sufficient annealing current is conducted within the word line 121, structures disposed upon and within the substrate 103 beneath (or proximal to) the word line 121 may be heated to an annealing temperature and thus effect a restorative annealing operation. Alternatively, one or more resistive elements (or structures or materials) may be added in series with conductive portions or segments of the word line or other heating element to establish a desired resistance. In the particular example shown, the word line 121 forms the control gate of a row of non-volatile storage cells 123 such as Flash memory cells or SONOS memory cells, each having a charge storage layer 127 sandwiched between a control-gate insulator (above the charge storage layer) and a tunneling oxide 129 (also an insulator), with the tunneling oxide disposed over an enhancement or depletion channel of a field effect transistor (the source, drain and channel of which are not shown, but typically formed within the substrate 103). By this arrangement, when the annealing current raises the word line temperature to a sufficient level, degradative oxide traps (trapped carriers) within the tunneling oxide 129 incrementally accumulated over a sequence of program/erase cycles, may be annealed out, thus reversing the program/erase-induced degeneration (similarly, in a SONOS architecture, carrier build-up within the charge storage/trapping layer may be expelled, restoring the non-volatile cells to virgin or near virgin condition).

FIG. 2B illustrates an alternative embodiment in which bit lines 141 within a cell array (e.g., a storage cell array or any other type of use-degraded semiconductor array having bit lines that are used to enable concurrent data transfer to/from to multiple cells) are used as heating elements by providing power delivery circuitry (described below, but not shown in FIG. 2B) to enable current conduction through the bit line. As with the word-line-based heating element of FIG. 2A, the intrinsic resistance 144 of the bit line itself (typically implemented in metal layer traces that extend across the length or at least partly across the length of the cell array) may establish the resistance of the heating element so that when a sufficient annealing current is conducted within the bit line, structures disposed upon and within the substrate beneath (or proximal to) the bit line 141 may be heated to an annealing temperature and thus effect a restorative annealing operation. In the particular example shown, the bit line 141 is coupled to one or more chains 142 of Flash memory cells (145₀-145_{N-1}, N being the number of Flash memory cells in the chain) in a NAND Flash arrangement (in the example shown, including a source-select transistor 147 (ss) at the grounded end of the chain and a drain-select transistor 149 to switchably couple the Flash memory cells 145 to the bit line 141), with word lines (WL₀-WL_{N-1}) extending across the cell array in a direction transverse to the bit line 141. Bit lines in other types of Flash memories (i.e., NOR Flash) and other types of cell arrays generally may be used as heating elements in a like fashion.

FIG. 2C illustrates another heating element embodiment, in this case, a metal, polycrystalline or other conductive structure 171 dedicated for heating purposes (in contrast to the dual-purpose bit lines and word lines which, at times are used as heating elements, and at other times as control lines to enable row operations, and data lines to enable data transfer, respectively) and disposed on-die and in proximity to use-degraded semiconductor components. In this particular example, the dedicated heating element 171 is disposed in proximity to transistors used in input/output driver circuits 173 (used to drive data signals d0-d(n−1) in response to corresponding logic level data values txd0−txd(n−1), and coupled between ground and supply rails 176 and 174), thus enabling annealing operations therein to correct undesired threshold-voltage (VT) mismatch which tends to develop over time due to oxide traps in the MOS transistors.

Although a dedicated heating element 171 is shown in FIG. 2C, one or more other pre-existing conductive lines, provided for functional purposes, may be leveraged as a heating elements for annealing operations. More generally, although specific examples of heating elements have been shown in FIGS. 2A-2C, combinations of such heating elements and/or numerous other types of conductive elements may be used as anneal-operation heat sources, including structures that generate heat through phenomenon other than I²R power dissipation.

B. Power Delivery

1. Voltage Mode, Current Mode

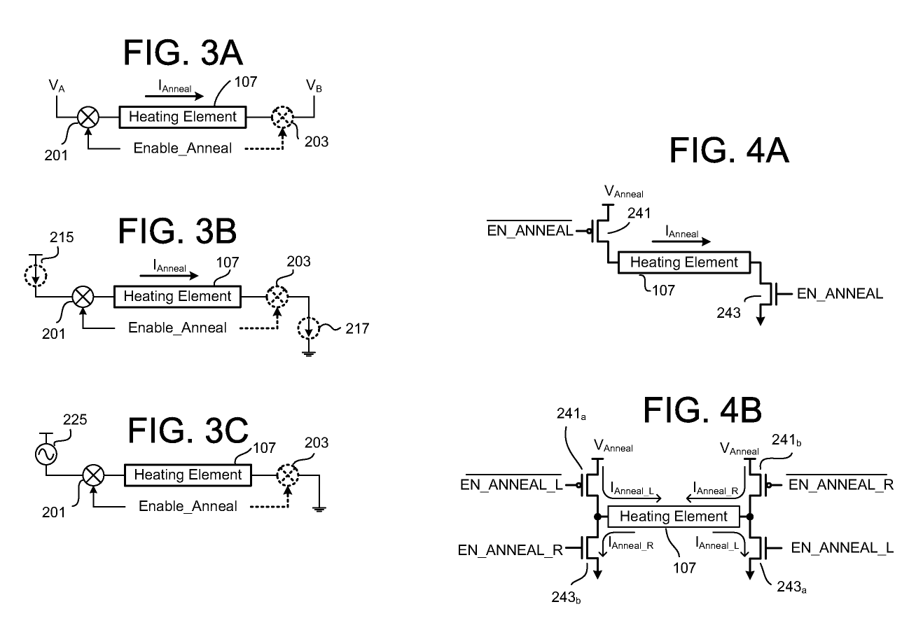

FIGS. 3A-3C illustrate examples of power delivery circuitry that may be provided within or in conjunction with an annealing circuit to power a heating element. FIG. 3A, for example, illustrates an embodiment in which a potential difference V_{A}-V_{B} is developed across a heating element 107 by switching one or two switch elements 201, 203 (e.g., pass gate or other transistor-based switch) to a conducting state in response to one or more enable signals (e.g., Enable_Anneal). In one embodiment, for example, V_{A} is established by an annealing voltage source and V_{B} is established by a ground reference node. Other voltage-node connections may be used. Also, in a more specific embodiment, annealing potentials (V_{A}−V_{B}) on the order of 20 to 30 volts, may be applied to create the desired annealing current (and thus the desired annealing temperature). Higher or lower annealing potentials may be used in other embodiments, and the annealing potential may be created on-chip using virtually any type of DC-DC converter (e.g., charge pump, buck-converter, etc.), or may be supplied from an external source. Also, in a device having a dedicated heating element at least, one of the two switch elements may be omitted as indicated by the dashed-outline depiction of switch element 203. The Enable_Anneal signal is asserted, in one example, by the anneal controller and thus enables the switches to be switched on or off according to the time selected for an anneal operation.

FIG. 3B illustrates an alternative embodiment of a power delivery circuit formed by a constant current source (e.g., a current mirror, current regulator or other digitally- or analog-controlled current source). As shown, the current source may be formed by circuitry 215, 217 on both sides of the heating element 107 or by circuitry on a single side of the heating element (hence, the dashed-outline of element 203). Also, the switching elements 201, 203 (which may be a single switching element when implementation permits) are controlled by the Enable_Anneal signal or respective enable signals as described in reference to FIG. 3A.

2. AC Power Delivery

FIG. 3C illustrates another embodiment of a power delivery circuit, in this case formed by an alternating voltage or current source 225, thus powering the heating element 107 through an alternating current. The actual voltage sources and/or current sources may be generated on-chip in any practicable manner or supplied by an external source. Also, while the far end of the heating element 107 is depicted as being coupled to ground (i.e., switchably coupled to ground if switch element 203 is provided), another DC or AC potential may be coupled to the far end of the heating element 107 instead.

3. Single-Side/Dual-Side Power-Delivery

FIGS. 4A and 4B illustrate exemplary arrangements for delivering power to a heating element within an annealing circuit. More specifically, in the embodiment of FIG. 4A, referred to herein as a single-side power embodiment, current flows from left to right across the heating element 107 in response to assertion of an enable signal (EN_ANNEAL) which, in an active-low instance, switches on P-MOS transistor 241, and in an active-high instance, simultaneously switches on N-MOS transistor 243, thereby switchably coupling an annealing potential (V_{Anneal}) across the heating element 107 to produce the annealing current. In the alternative embodiment of FIG. 4B, referred to herein as a dual-side power embodiment, two different anneal-enable signals are asserted at different times (EN_ANNEAL_L and EN_ANNEAL_R), enabling left-to-right current flow, I_{Anneal}_{_{—}}_{L}, through transistors 241a and 243a when EN_ANNEAL_L is asserted, and enabling right-to-left current flow, I_{Anneal}_{_{—}}_{R}, through transistors 241b and 243b when EN_ANNEAL_R is asserted. As discussed below in the context of a specific Flash memory implementation, the dual-side power embodiment may reduce storage-disturb effects by balancing the higher potential (a voltage gradient develops along the heating element due to distributed IR drop) between the left and right sides of the heating element, thereby halving the application of storage-disturb potential to any single side of a row of storage cells.

C. Heating Control

As briefly discussed above, annealing temperatures may vary according to the type of structures or materials to be annealed, the proximity of the heating element to the degraded structures/materials, the level of degradation exhibited by the degraded materials, and possibly even secondary considerations such as wear of the annealing circuitry itself and the number of times a structure or material has been annealed. Accordingly, even in embodiments, where a known annealing temperature is desired, it may be desirable to provide some control over the temperatures generated and/or the specific locale at which heat is generated.

1. Heating Element Geometry (Width Modulation, Segmentation)

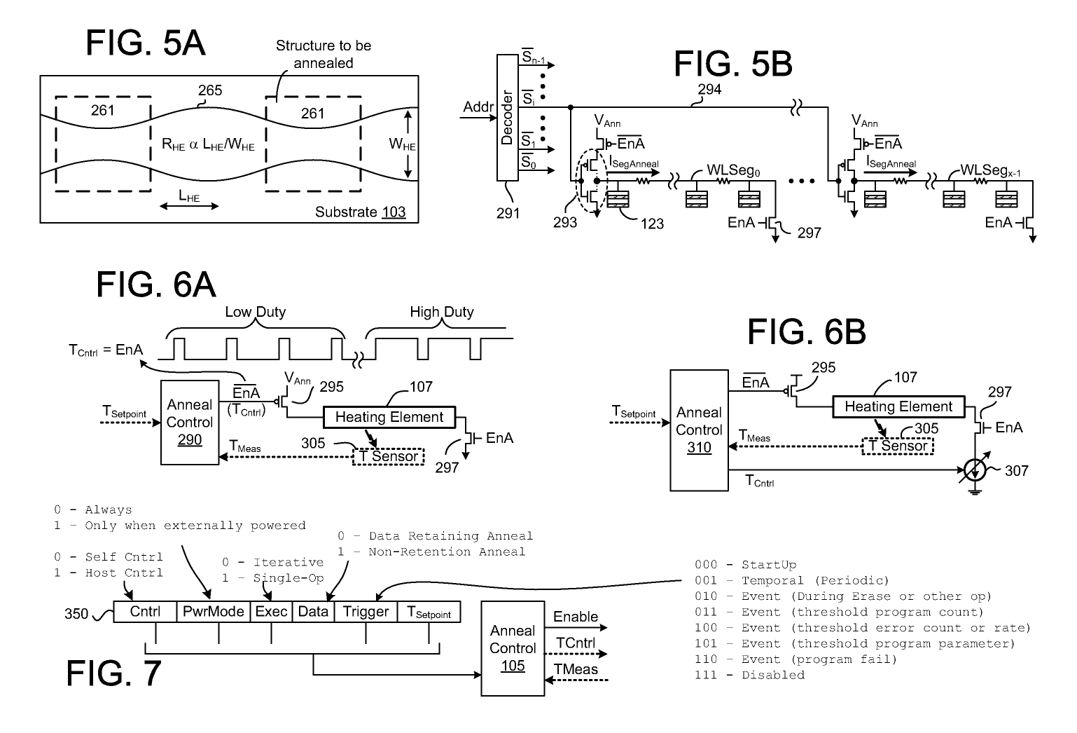

In embodiments where known annealing temperatures are desired, and resistive heating elements with known annealing voltages are to be applied, generating the desired temperature is generally a function of the annealing element resistance, a value itself proportional to the length of the heating element and inversely proportional to the width of the heating element at any point along its length. Accordingly, in one embodiment, shown in FIG. 5A, the overall resistance (R_{HE}) of a heating element 265 of given length (L_{HE}) may be controlled by modulating, at device fabrication time or through post-fabrication trimming, the width of the heating element (W_{HE}). In the case of a polysilicon heating element such as a word line, for example, the width of the heating element may be set (or trimmed) uniformly along the length of the element to establish a desired resistance (R_{HE} being proportional to L_{HE}/W_{HE}), or the width may be modulated (tapered or varied at certain positions of interest or regular intervals along the length) to effect an average resistance of the heating element, with localized hot spots. In the embodiment of FIG. 5A, for example, the heating element width is narrowed in regions that are disposed over or are otherwise proximal to the structures/materials to be annealed 261, thus enabling development of desired annealing temperatures within the device at specific locations instead of arbitrarily or evenly along the length of the heating element 265.

FIG. 5B illustrates an alternative manner of establishing a desired resistance within a heating element, in this case through segmentation of an otherwise continuous structure such as a word line or bit line (or other structure which, due to its alternate, non-heating function, tends to be continuous within the integrated circuit). Taking the example of a word line as shown in FIG. 5B, instead of providing a single continuous word line that extends across a complete row of cells in an array, the word line is decomposed into multiple (X) word line segments, WLSeg0-WLSegx−1, each having a length that provides a desired word line resistance and thus a desired level of power dissipation (heat generation) when a desired annealing current is conducted. Note also that, in contrast to a conventional word line arrangement, a transistor switch 297 is provided on the far end of each word line segment (i.e., as part of the power delivery circuit) to enable current flow through the word line segment instead of merely charging of the word line segment. Still referring to the embodiment of FIG. 5B, each of the word line segments is coupled to an inverter driver 293 which grounds the word line segment when a shared select signal (S1, ‘i’ being an integer between 0 and n−1) is deasserted (high in this case) on select line 294, and couples an annealing voltage (or read or write voltage in other operations, which read and/or write voltage may be the same as the annealing voltage) to one side of the word line segment (through P-MOS transistors controlled by the select signal (S1) and the anneal-enable signal (EnA), respectively) and grounds the opposite side of the word line segment (via transistor 297), thereby establishing the segment annealing current, I_{SegAnneal}, through the word line segment and thus an annealing heat source for the structures/materials in proximity to the word line (non-volatile storage cells 123 in this example). Note that transistor 297 may also be used during other operations, for example, to more rapidly discharge the word line after a read or write operation. Also, snap-back protection circuitry or other circuit components not shown may be included within the word line driver circuitry of FIG. 5B and other word line drivers herein.

2. Temperature Control

As discussed briefly above, it may be desirable to provide some measure of temperature control within or as part of the annealing circuitry, thus enabling temperature to be adjusted, for example, upon determining that annealing operations are partly or wholly ineffective to reverse degradation, or to enable different temperatures to be used in different types of annealing operations. For example, it may be desirable to apply lower annealing temperatures during data-retaining anneal operations (discussed below), than non-retaining anneal operations such as erase-and-anneal operations (also discussed below). Moreover, even in the case of single-temperature anneal, it may be desirable to provide a closed-loop control to ensure that annealing temperature does not become too high (which may result in device destruction) or remain too low (resulting in partially or wholly ineffective anneal). Accordingly, in various embodiments, some manner of providing a setpoint temperature, dynamically adjusting the amount of heat generated by the heating element and/or measuring the heat or indication thereof may be provided within or as part of the annealing circuitry.

a. Pulse-Width Modulated Temperature Control (Closed-Loop Vs. Open Loop, Variable Setpoint Vs. One-Time-Programmed or Hardwired)

FIG. 6A illustrates an embodiment of an anneal controller 290 that optionally receives a temperature setpoint signal, T_{Setpoint} (e.g., from an on-chip register or configuration circuit or from an external source), and that modulates the duty cycle of an enable signal, EnA, to control the amount of power delivered to a heating element 107, and thus the annealing temperature. Thus, in this embodiment, the enable signal itself corresponds to the temperature control signal, T_{Cntrl}, in the more general embodiment of FIG. 1. Still referring to FIG. 6A, a temperature sensor 305 (e.g., based on thermocouple principle or any other manner of measuring directly, or indirectly, the temperature of the heating element or the amount of heat energy flowing to the material/structure being annealed) may optionally be provided to feedback a temperature indication (e.g., measured-temperature signal, T_{Meas}) to the anneal controller 290, thus enabling closed-loop temperature control. Considering the open-loop embodiment first (i.e., no temperature sensor or disabled feedback loop), the anneal controller 290 may include pulse-width modulation circuitry to modulate the duty cycle of the enable signal in accordance with a digital or analog setpoint value, thus enabling different levels of annealing energy to be delivered to the heating element and thereby control the annealing temperature. Specifically, when EnA is asserted (i.e., high such that /EnA is at logic low level), transistors 295 and 297 are switched on and thus enable conduction of the annealing current. When EnA is deasserted, transistors 295 and 297 are switched off (i.e., switched to a substantially non-conducting state), halting the annealing current. Accordingly, by driving the EnA signal with lower or higher duty cycles (or, said another way, with narrower or wider pulse widths), different amounts of energy may be delivered to the heating element 107 to achieve different annealing temperatures. In the closed loop embodiment, an error signal may be generated within the anneal controller 290 by subtracting the T_{Meas} signal (or digitized version thereof) from the T_{Setpoint} value (which may be a hard-coded or one-time-programmed setpoint value), and the error signal used to control the duty cycle modulation (i.e., pulse width modulation) of the enable signal, incrementally or error-proportionally increasing the enable signal duty cycle when the measured temperature falls short of the setpoint and incrementally or error-proportionally reducing the enable signal duty cycle when the measured temperature exceeds the setpoint value.

b. Current-Modulated Temperature Control (Closed-Loop Vs. Open Loop, Variable Setpoint Vs. One-Time-Programmed or Hardwired)

FIG. 6B illustrates an alternative temperature control arrangement in which an anneal controller 310 outputs a temperature control signal T_{Cntrl} to adjust a current source 307 (or voltage source) and thus directly increase or reduce the annealing current flowing within heating element 107 during an anneal operation (e.g., when an enable signal, EnA, is asserted to switch on transistors 295, 297 and thus enable an anneal operation). The temperature control signal may be an analog signal (e.g., one or more bias voltages) or a digital signal having respective bits, for example, to switch on respective current sinking or sourcing transistors (which may be binary weighted, thermometer coded, etc. to provide current control with a desired granularity; and/or a linearity or nonlinearity). As in the embodiment of FIG. 6A, the temperature sensor 305 may be omitted and the anneal controller 310 enabled to function in an open loop manner in response to a temperature setpoint input (T_{Setpoint}). Also, if the temperature sensor 305 and closed-loop control circuitry is provided, the temperature setpoint may be an input (e.g., from an on-chip register or configuration circuit, or from an off-chip source) or may be hardcoded or one-time-programmed within the anneal controller 310 (or other portion of the annealing circuitry).

### III. Annealing Operation

In the various embodiments of annealing circuits described above, the anneal controller initiates an annealing operation, for example, by outputting an enable signal to the heating circuitry. There are a variety of alternative approaches for determining when to anneal and, particularly in systems containing a large volume of structures to be annealed (e.g., cell arrays which may include many millions of cells to be annealed), how to execute the overall device anneal operation, and whether the anneal is to be performed in a manner that preserves some state (e.g., stored data) in the material/structure being annealed.

A. Triggering an Anneal

Two broad classes of techniques that may be employed to determine when to initiate or trigger an anneal operation include deterministic approaches in which the time for anneal is fixed relative to device power-up time, and event-driven approaches in which anneal operations are initiated in response to detecting a particular condition other than elapse of time. Within these broad classes, the circuitry for determining whether an anneal is to be initiated may be disposed within the integrated circuit device in which the anneal is to be performed (self-controlled anneal) or within an external device (externally-controlled anneal), or both.

1. Deterministically-Triggered Anneal

In one embodiment, an annealing operation is performed deterministically, at every device power-up. This power-up anneal may be limited to starting from a complete power-down state (when a system including the integrated circuit device to be annealed is first started up), or from one or more reduced-power modes of operation (e.g., sleep modes, standby modes, etc. in which selected circuit components may be powered down to conserve power. In another embodiment, annealing operations may alternatively or additionally be performed periodically, upon determining that a predetermined amount of time has elapsed since the most recent anneal operation. In such an embodiment, a counter may be provided (e.g., within the anneal controller 105 of FIG. 1) to count transpired clock cycles until a threshold count is reached, or other manner of determining elapsed time may be employed.

2. Event-Triggered Anneal

Embodiments employing event-triggered anneal include embodiments for performing an anneal in response to determining that:
other operations that may be performed concurrently with anneal operations are to be executed (opportunistic anneal),
a threshold number of degradation-inducing operations have been performed since the last anneal operation (wear-based anneal)
a threshold level or rate of error is occurring (error-triggered anneal)
a failure or near-failure has occurred (performance-triggered anneal)

Opportunistic anneal operations may be performed in response to detecting that other types of operations, compatible with simultaneous or at least concurrent (at least partly overlapping in time) execution of anneal operations, are to be performed. For example, an erase operation (e.g., a block erase) within a Flash memory device or SONOS memory device typically requires hundreds or even thousands of microseconds, and involves raising the substrate or body voltage to a potential that results in reverse tunneling of charge from the charge-storage layer (floating gate, nitride layer, etc.) back to the substrate. Simultaneously with such operations, annealing currents may be conducted within word lines, bit lines and/or other heating elements to carry out annealing operations, thus hiding the overhead required for annealing operations under the erase operation. If time required to complete the anneal operation is greater than the time required to perform the parallel (concurrent) operation, the anneal operation may be decomposed into multiple stepwise anneal operations, any number of which may be performed opportunistically (i.e., when other anneal-hiding operations are being performed) or when required for other reasons (e.g., need to restore the annealed circuitry to normal service). The piecewise anneal operations may be performed back-to-back or at times separated by one or more intervening operations. Other types of opportunistic anneal operations may be performed whenever the resources and bias voltages/currents applied in the annealing operation will not interfere with the other concurrently executed operation. Also, anneal operations may be performed after specific operations before restoring use-degraded structures to normal service. For example, anneal operations may be performed after each block erase cycle in a non-volatile memory before or after restoring an erased block to service.

Wear-based anneal operations may be performed in response to determining that a threshold number of degradation-inducing operations have been performed since the last anneal. In a Flash memory device (or system) utilizing memory cell technology such as Floating Gate (FG) or SONOS or TANOS, for example, the total number of programming operations (e.g., program/erase cycles) performed on individual storage cells, or groups or blocks or clusters of storage cells, may be tracked (e.g., by an operation counter) to determine an estimated wear level in those cells. When a threshold number of programming operations have been performed (e.g., determined by comparing the operation counter output to the threshold in a comparator circuit), an anneal operation may be initiated (e.g., scheduling or initiating anneal in response to a signal indicating need for same from the comparator circuit). Similar arrangements may be used to keep track of other wear-inducing operations and triggering anneal operations. Also, separate operation counters may be maintained for respective sets of memory cells that are annealed as a group (e.g., operation counter per storage block, with the entire block being annealed in an anneal operation or set of anneal operations performed in sequence).

Embodiments for carrying out error-triggered anneal operations generally include circuitry for detecting errors and signaling the need for one or more anneal operations in response to determining that the quantity of errors or the rate of error has reached a predetermined or programmed threshold (all such thresholds for triggering anneal may be predetermined or programmed within the anneal-controlling device). For example, in one embodiment, error detection circuitry (i.e., circuitry for detecting errors and for flagging memory sections or pages with large fail counts) is provided to determine the presence of error in a data value retrieved from memory (such error, if present, indicating either a failure to properly write or read the data value and/or failure to retain the data value) and to count the detection of that error as a function of elapsed time (error rate) and/or as a percentage of such operations performed (error quantity). As an aside, programming of a Flash memory cell may be performed iteratively with a number of short program steps followed by read operations to verify the state of the memory cells. When more programming steps are required to program a memory cell, the memory cell is impliedly beginning to wear out. If the error rate or error percentage exceeds the programmed or predetermined tolerance threshold, anneal operations may be performed or scheduled. Examples of such error detecting circuitry include circuits for evaluating parity bits, checksum values, cyclic redundancy check values, and/or error correction code (ECC) values to determine presence of data errors. Other type of error detection circuitry include circuits for comparing known data to test data (e.g., loopback testing circuits) to determine error rates and/or error quantities.

Embodiments for carrying out performance-triggered anneal operations include circuitry for detecting a failure or near failure and scheduling/performing anneal operations in response. For example, in a Flash memory device, a monitoring circuit may be provided to determine when the number of program/verify cycles (or program steps) required to program a given storage cell or group of storage cells exceeds a predetermined or programmed threshold or increases by some predetermined percentage or number of steps (triggering an anneal operation or scheduling the anneal when the threshold is exceeded), and/or program failure (unable to verify after specified number of program/verify cycles) may automatically trigger an anneal operation. Another approach for determining when an anneal is needed is to track the shift of Vt distribution with memory writes and trigger a longer anneal after a certain threshold has passed. This particular approach may be particularly useful for SONOS or TANOS memory cells. More generally, any type of circuit capable of determining performance degradation (e.g., amplitude mismatch in parallel-transmitted signals due to progressively worsening VT mismatch) may be provided to trigger anneal operations.

3. Trigger Source (Self-Triggered vs. Externally-Triggered Anneal)

Triggering circuitry, whether deterministic, event-driven or both (note that any combination of the triggering embodiments described above may be employed) may be provided within the integrated circuit device containing the annealing circuitry (the “anneal-enabled IC”) and/or on a host device that issues annealing commands to the anneal-enabled IC. For example, in a self-triggered embodiment, the on-die anneal control controllers 105, 290, 310 described in reference to FIGS. 1, 6A and 6B, and below in reference to FIG. 7, may include circuitry for initiating any or all of the deterministic and event-driven anneal operations described above. Alternatively (or additionally), in an externally-triggered embodiment, a host device such as a Flash memory controller, processing unit, application-specific-integrated circuit (ASIC), etc. may include circuitry for initiating any or all of the deterministic and event-driven anneal operations described above. In the externally-triggered case, the host device may issue global anneal commands to trigger device-wide anneal operations (or at least issue commands lacking specificity as to the region of the device to be annealed), or may issue targeted anneal commands, specifying the particular region or circuitry to be annealed within the anneal-enabled IC. For example, the host device may issue an anneal command in conjunction with an address value that specifies a row or other region of a storage array in which an anneal operation is to be performed. Alternatively, an address counter (e.g., to contain a row address) may be maintained on the anneal IC and incremented after each global anneal command.

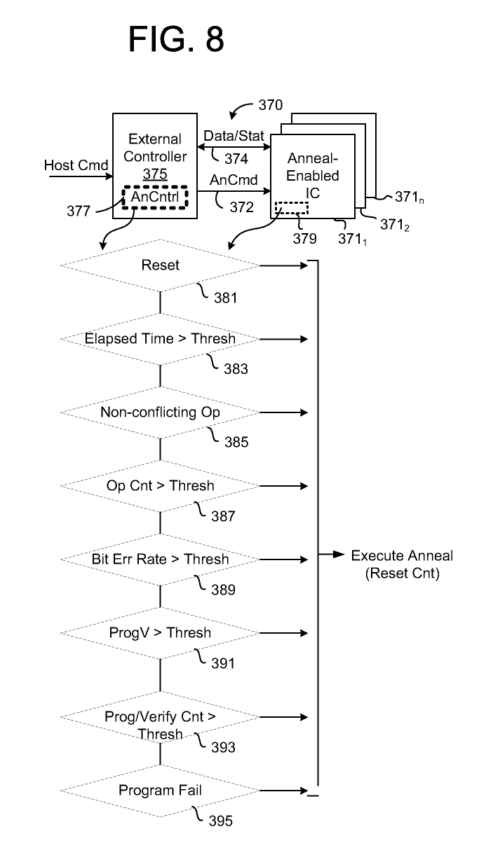

FIG. 8 illustrates an embodiment of a system that includes one or more anneal-enabled ICs 371₁-371ₙ and an external controller 375. Examples of such a system include a non-volatile memory system formed by one or more Flash, SONOS or other non-volatile memory devices (e.g., anneal-enabled ICs 371) each having an on-die controller (in which an anneal controller may be disposed), and an external controller coupled to the non-volatile memory devices through a signaling interface 370. In FIG. 8, the memory access interface is generalized to show a command path 372 (or request path or instruction path) to convey anneal commands (AnCmd), programming/configuration commands and/or other commands from the external controller 375 to the anneal-enabled ICs 371, and a data/status path 374 to enable data to be transferred between the external controller 375 and the anneal-enabled ICs 371. The data/status path 374 may also be used to convey status information from the anneal-enabled ICs 371 to the external controller 375, including information that may be used determine whether to initiate/schedule anneal operations (i.e., issue anneal commands). Note that other types of signaling interfaces having more or fewer distinct signaling paths may be used to convey information between the external controller 375 and anneal-enabled ICs 371 in alternative embodiments.

In the particular embodiment of FIG. 8, anneal operations are performed, for example and without limitation, on detection of reset (381), elapsed time (e.g., since last anneal) greater than threshold (383), execution of or scheduling execution of a non-conflicting operation (385) (e.g., hiding the anneal under an erase operation within a Flash memory device), number of degradative operations (Op Cnt) greater than threshold (387) (e.g., count of program/erase operations in a Flash memory device exceeds a predetermined or programmed threshold), bit error rate greater than threshold (389), program voltage (a value that may be incrementally increased in successive program/verify cycles within a non-volatile memory device in an effort to complete a programming operation) increased beyond a threshold (391), program/verify cycle-count (i.e., count of program/verify operations required to achieved desired level of device programming) greater than threshold (393), or program operation failure (395). More or fewer triggers for anneal execution may be provided in alternative embodiments. Also, as shown, circuitry 377, 379 for tracking the various triggering events (and/or elapsed time) may be provided within the external controller 375 and/or one or more of the anneal-enabled ICs 371.

4. Scheduled Anneal

Note that the anneal operations described above, however triggered, may be performed in an on-demand or scheduled fashion. Following the example of a non-volatile memory device (e.g., a Flash or SONOS memory device), in an on demand anneal, anneal operations may be performed by tracking the number of non-volatile storage blocks (or other circuit regions) marked as requiring anneal and then executing one or more anneal operations upon determining that a threshold has been reached. As an aside, a storage block may be marked for anneal in a manner similar to marking a bad block in a NAND Flash memory device. That is, memory management software, executed by an on-chip or off-chip state machine or processing circuitry, may check the status of a block (or page) before using it, determine whether the block is marked as bad and/or whether it needs annealing, and then mark the block accordingly by recording status information corresponding to the block in a status memory or register.

As an alternative to on-demand anneal (i.e., performing anneal operations upon determining that a threshold has been reached), anneal operations may be scheduled for a later time. For example, in one embodiment, upon determining that a threshold has been reached (e.g., threshold number of blocks marked as requiring anneal), anneal operations are scheduled for execution during periods when memory is inactive or resources are otherwise available or underutilized.

B. Programmed Anneal Parameters

FIG. 7 illustrates an embodiment of a mode register 350 (or configuration circuit) optionally provided within an anneal-enabled IC and that may be programmed in response to host commands (or one-time programmed, for example, during device production) to provide flexible control over triggering and execution of anneal operations. In the particular embodiment shown, the register 350 includes a control field (Cntrl), power-mode field (PwrMode), execution field (Exec), data field (Data), trigger field (Trigger), and setpoint field (T_{Setpoint}). More or fewer fields may be provided in alternative embodiments (e.g., to provide other aspects of control), and/or any or all of the fields may be disposed within separate registers of the annealing IC.

In one embodiment, the control field enables a selection between self-control and host-controlled modes of annealing operation as discussed above (i.e., device either self-triggers anneal operations, or responds to commands from a host device). The power mode field is provided to control whether anneal operations are limited to times in which the anneal-enabled IC is powered by an external source (e.g., when a mobile device containing anneal-enabled IC is plugged into a wall outlet, docking station or otherwise receiving battery-charging power), or is full-time enabled to perform anneal operations. Finer granularity to distinguish between additional levels of power-saving modes may be provided in alternative embodiments. The execution field is used to control the manner in which annealing operations are carried out within a device having multiple separately annealable regions. For example, in a Flash memory device, each word line (or collection of word line segments) may define a separately annealable region of the device. In such an embodiment, if the execution field indicates single-operation anneal (Single-Op), all word lines may be heated simultaneously to perform an anneal operation. Conversely, if stepwise-anneal is selected (e.g., Exec=0), one region may be annealed at a time in a sequence of anneal steps (e.g., one word line after another may be selected and heated to carry out anneal operations in a stepwise fashion). In alternative embodiments, groups of annealable regions (e.g., those regions sufficiently separated from one another to avoid over-temperature conditions when simultaneously heated or those close enough to make heating of a region more power efficient) may be selected for simultaneous anneal. Also, finer control over number of simultaneously selected heating elements may be provided by expansion of the execution field to include more than a single bit).

The data field indicates whether the anneal operation is to be performed in a manner that retains data (special biasing considerations may apply as discussed below) or is a non-data retaining anneal. In some cases, this selection may be one of compromising between speed-of-anneal and avoiding loss of data, as circumstances may warrant.

The trigger field includes values that enable selection between various deterministically-triggered and event-triggered anneal operations (and to disable anneal operations altogether, Trigger=111). In the particular embodiment shown, the trigger field includes three bits, thus enabling selection of one of eight triggering modes. In alternative embodiments, additional bits may be provided to enable independent selection of the various triggering modes.

The setpoint field (T_{Setpoint}) enables specification of a temperature setpoint. In alternative embodiments where alternate selection between different annealing temperatures is desired, multiple temperature setpoint fields may be provided.

Note that numerous additional control values may be recorded within the register 350 (or associated registers or configuration circuits) including, without limitation, any of the triggering thresholds described above. Also, any or all of the anneal-control parameters described above may alternatively be indicated by control fields included within or associated with an anneal command received from a host device.

C. Data Retention During Anneal

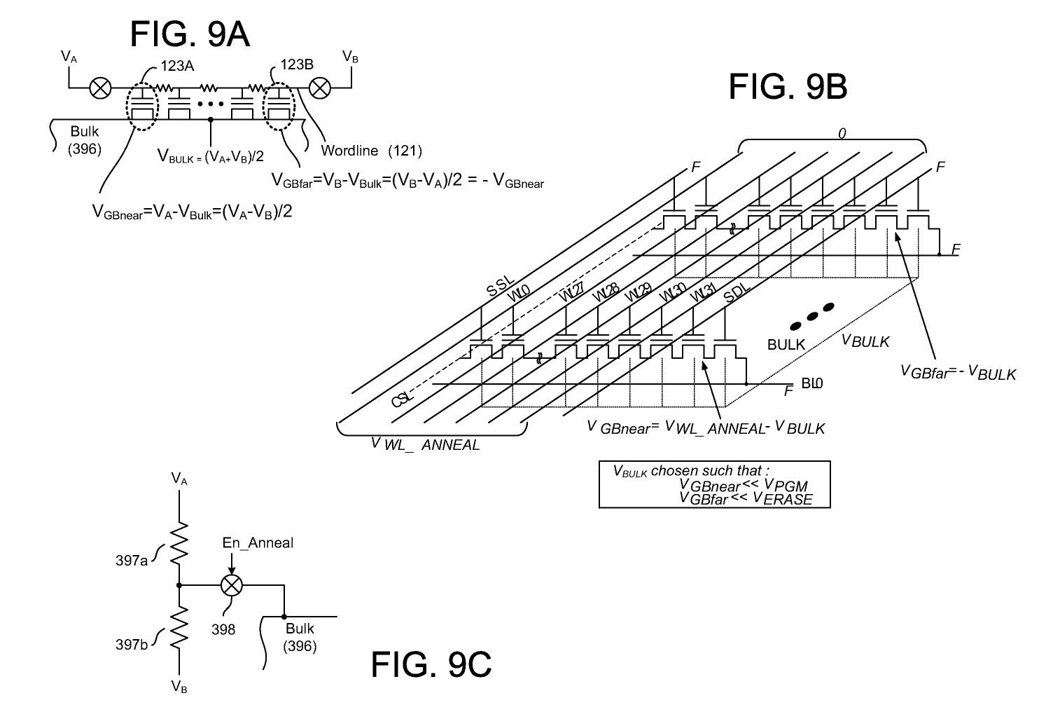

In a number of the anneal circuit embodiments described above, voltages applied across the heating element during run-time operation may undesirably affect the state of the annealed structures. For example, where word lines (or control gates) in a non-volatile storage array are used as heating elements, the anneal voltage will appear at the word-line driver side of the array and, if high enough, may result in undesired programming (attracting charge to the charge storage layer) of the underlying non-volatile storage elements. In one embodiment, this undesired programming is avoided through biasing of the bulk substrate (or bulk, which may include any wells in which annealed structures are formed) to a potential that lowers the gate-to-bulk voltage for the non-volatile storage cells to a potential below that required for cell programming. Referring to FIG. 9A, for example, in one embodiment, the bulk 396 is charged to a voltage that is substantially centered between the voltages applied to opposite ends of the word line 121 (i.e., V_{BULK} is set midway between V_{A} and V_{B} or V_{BULK}=(V_{A}+V_{B})/2), thus halving the positive gate-to-bulk voltage, V_{GB}, that would otherwise be applied across non-volatile storage cell 123A (referred to herein as a near-side storage cell due to its proximity to a word line driver, not shown). Note that charging the bulk to the V_{A} potential (assuming V_{A} to be more positive than V_{B}) is also an option and may be carried out to ensure that no programming occurs in a fully erased row of storage cells, but that, due to the grounded end of the word line at non-volatile storage cell 123B (the far-side storage cell), a negative voltage equal in magnitude to the difference between V_{A} and V_{B} would appear across non-volatile storage cells 123B. Accordingly, by biasing the bulk to (V_{A}+V_{B})/2 during an anneal operation, a balance is achieved, setting the amplitude of the positive and negative potentials across cells 123A and 123B at (V_{A}−V_{B})/2; half the worst-case potential that would be applied across either storage cell if the bulk was biased to V_{A} or to V_{B}. Assuming for the sake of illustration that the V_{A} and V_{B} potentials are 20 volts and ground, respectively, then the bulk may be biased to 10 volts to ensure that no voltage more than positive or negative than 10 volts is applied across any of the storage cells 123, thus ensuring that program and erase operations that require potentials substantially greater than 10 volts do not inadvertently occur. Accordingly, data stored in the non-volatile storage cells 123 may remain undisturbed during the anneal operation, thus permitting run-time anneal operations to be performed in regions of memory containing valid data.

FIG. 9B provides a perspective view of the bulk programming arrangement described above in the context of a NAND-type Flash memory device, showing exemplary non-volatile storage cell chains coupled to respective word lines WL0-WL31 (there may be more or fewer word lines per cell chain in alternative embodiments) as well as select-source lines (SSL) and select-drain lines (SDL) for controlling source-select and drain-select transistors. As shown, the bulk voltage is chosen such that the gate to bulk voltage, V_{GB}, is midway between the applied anneal voltage (V_{WL}_{_{—}}_{ANNEAL}) and ground or, more generally, so that the gate to bulk voltage across each non-volatile cell is substantially lower in magnitude than both the cell program voltage, V_{PGM}, and the cell erase voltage, V_{ERASE}.

FIG. 9C illustrates an embodiment of a bulk biasing circuit that establishes the bulk voltage midway between the V_{A} and V_{B} potentials applied to either end of a word line (or other heating element) during an annealing operation. As shown, resistive elements 397a and 397b, which may be implemented on-chip or off-chip and by active and/or passive components or any combination of active and passive components, are coupled in a resistor divider configuration to establish VA+VB/2 at switch node 398 (i.e., assuming equal resistances for elements 397a and 397b). By this arrangement, when an anneal operation is triggered (i.e., enable signal En_Anneal asserted), switch element 398 (i.e., a transistor switch or pass gate or any other switching structure) is switched to a conducting state to apply the desired midpoint bias voltage ((VA+VB)/2) to the bulk 396. Note that the foregoing assumes equal resistances for elements 397a and 397b, though the resistive values of such elements may also be unequal for example establish increased tolerance with respect to either the device programming or erase voltage. Further, the resistive values of elements 397a and/or 397b maybe programmatically adjusted (e.g., through production-time or run-time register programming or one-time programming operation) to establish a desired voltage divider ratio. More generally, bulk biasing circuits are not limited to the resistor-divider approach shown. Any circuit for generating the desired bulk biasing voltage may be used in alternative embodiments.

Also, other approaches for mitigating data loss during anneal operations include constructing the integrated circuit in such a manner to enable desired annealing temperatures to be reached with lower applied voltages. For example, a Flash memory chip (or other anneal-enabled integrated circuit device) may be constructed on a silicon-on-insulator (SOI) substrate to improve the ability to anneal with modest currents through the control gate.

D. Confirming Efficacy of Anneal Operation—Post-Anneal Generally

After an anneal operation has been performed, a number of techniques may be applied to determine whether the annealing process was successful. In one embodiment, for example, annealed circuitry is restored to normal service so that other fail/error-detect mechanisms can ensure its proper operation. For example, in a Flash memory device, annealed blocks may be marked as normal and returned to service. If the block fails later programming (or exhibits bit errors or other failures) it can be marked as bad and marked as a candidate for further anneal. A separate flag (or counter) may be provided to indicate that a block has been previously annealed (or how many anneal operations have been performed in total or since last failure detection). In this way, if the block fails after an anneal (or threshold number of anneal operations) it may be marked as permanently bad so that further anneal attempts are prevented. Note that, in this regard, anneal operations may generally be performed on blocks marked as bad (e.g., due to bit errors or other faults) to determine if they blocks may be repaired. Alternatively, anneal operations may be omitted on certain blocks (e.g., blocks factory-marked as bad blocks, as opposed to run-time marked; separate information fields may be provided to enable this distinction) since such determination may have resulted from more extensive testing. On the other hand, anneal may be used after factory test in an attempt to repair “bad” blocks or pages.

### IV. Examples of Specific Anneal-Circuit Embodiments

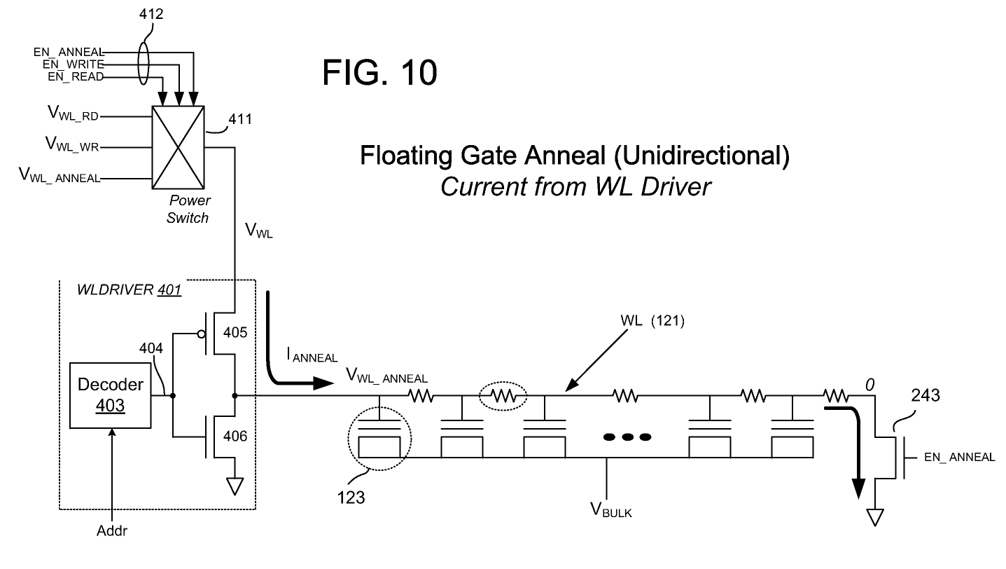

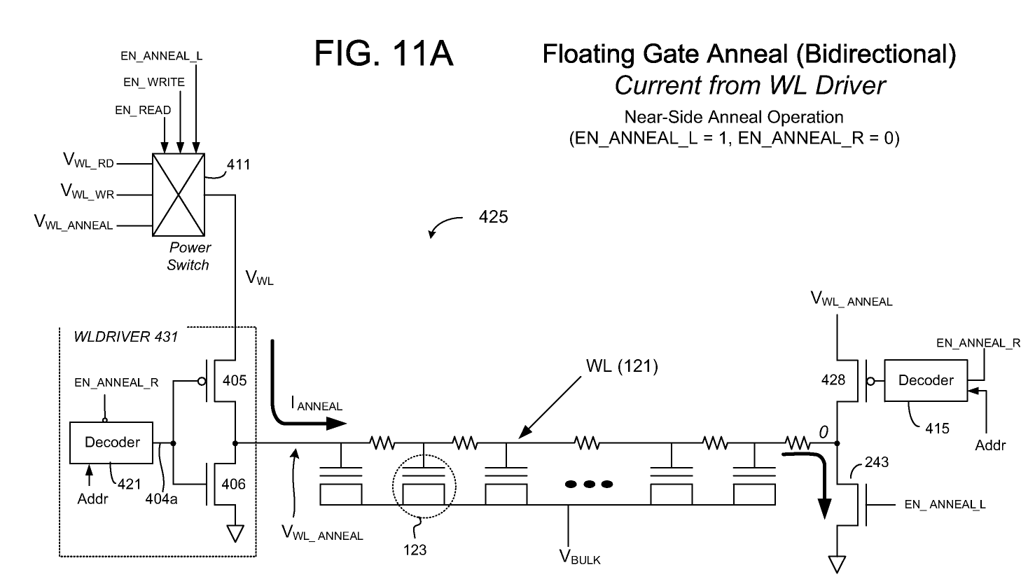

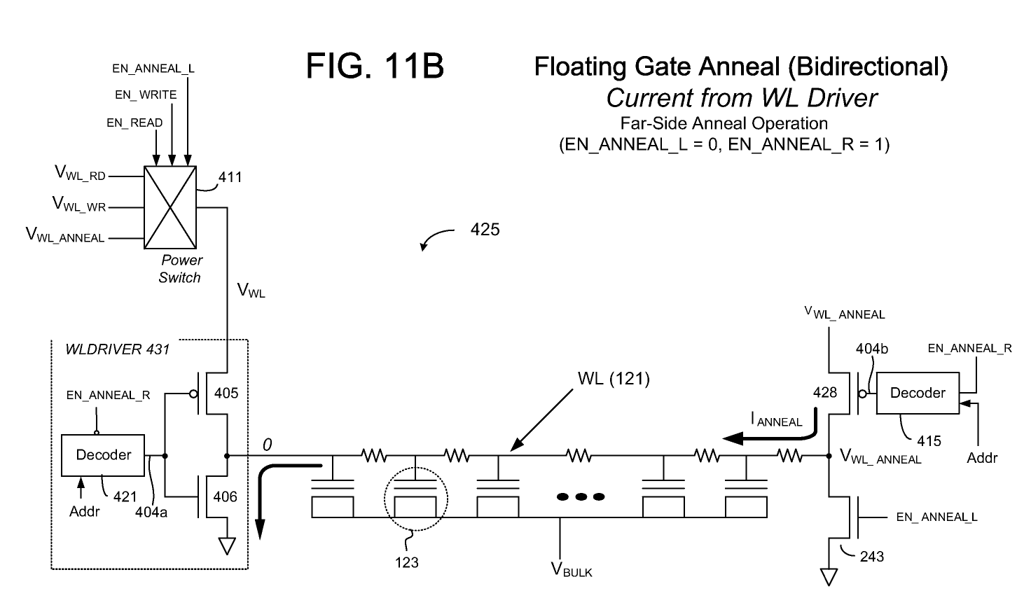

FIGS. 10, 11A and 11B illustrate particular embodiments of an annealing circuit in accordance with the principles and embodiments of FIGS. 1-9. More specifically, in the embodiment of FIG. 10, a word line 121 is accessed via word line driver 401 and used as a heating element to anneal damaged insulators within non-volatile storage cells 123 (e.g., Flash memory cells or SONOS memory cells). The word line driver 401 includes a decoder 403 that asserts (i.e., lowers in this example) one of 2^{M}−1 word-line-select signals 404 (only one of which is shown in FIG. 10) in response to an M-bit address (Addr), thereby switching on word-line driver transistor 405 and switching off word-line discharge transistor 406. By this operation, a voltage (V_{WL}_{_{—}}_{ANNEAL}, V_{WL}_{_{—}}_{WR} or V_{WL}_{_{—}}_{RD}) selected by power switch 411 in response to an operation select signal 412 (i.e., EN_ANNEAL, EN_WRITE, EN_READ, individually asserted according to whether an anneal, write or read operation is to be carried out) is applied to the word line 121 via transistor 405 to enable the selected operation. In particular, during an anneal operation, EN_ANNEAL is asserted to apply the anneal voltage, V_{WL}_{_{—}}_{ANNEAL} to the word line 121 and to switch on ground-path transistor 243, thereby enabling an annealing current, I_{ANNEAL} to flow through and heat the word line 121. Note that, in alternative embodiments, the write voltage (V_{WL}_{_{—}}_{WR}) or read voltage (V_{WL}_{_{—}}_{RD}) may suffice as the annealing voltage, so that a separate anneal voltage input to the power switch 411 may be omitted. Also, the anneal voltage (or any of the voltages supplied to the power switch 411) may be generated on-chip as discussed above, or provided from an off-chip source. Further, other on-chip structures (e.g., bit lines or dedicated heating elements) may be used as the heating element in alternative embodiments.

FIGS. 11A and 11B illustrate an alternative on-chip annealing embodiment 425 in which annealing current may be sourced from either side of a word line 121. The annealing circuitry includes a word line driver 431, power switch 411 and ground-path transistor 243 that operate generally as described in reference to FIG. 10, as well as a far-side decoder 415 and far-side word-line driver transistor 428. Within word line driver 431, operation of the address decoder 421 is selectively disabled and enabled by a far-end enable signal, EN_ANNEAL_R (enabling annealing current to be delivered from the far-end or right-side of the word line 121). Referring first to the near-side anneal operation shown in FIG. 11A, decoder 421 is enabled to lower an address-selected one of word-line select signals 404a when the far-end enable signal is deasserted, thereby applying a power-switch-selected voltage to the word line 121 via transistor 405 (and shutting off transistor 406) as discussed above. At the same time, near-side anneal enable signal (EN_ANNEAL_L) is asserted to enable V_{WL}_{_{—}}_{ANNEAL} to be applied to the word line 121 via transistor 405, and ground-path transistor 243 is switched on to enable an annealing current (I_{ANNEAL}) to flow through and heat the word line 121 (and thus anneal damaged structures within non-volatile storage elements 123).

Turning to the far-side anneal operation shown in FIG. 11B, far-side enable signal, EN_ANNEAL_R, is asserted, causing decoder 421 to deassert (raise) all word line select signals 404a, thereby switching on transistor 406 to provide a ground path and switching off transistor 405 to decouple the near-side word line voltage source. The far-side enable signal, EN_ANNEAL_R, also enables operation of the far-side decoder 415 which, in response, asserts (i.e., lowers) an address-selected one of far-side word-line select signals 404b (only one of which is shown) to switch on far-side word-line driver transistor 428 and thus deliver an annealing current in the direction shown.

### V. Circuit Manifestations Recorded on Computer-Readable Media

It should be noted that the various circuits disclosed herein may be described using computer aided design tools and expressed (or represented), as data and/or instructions embodied in various computer-readable media, in terms of their behavioral, register transfer, logic component, transistor, layout geometries, and/or other characteristics. Formats of files and other objects in which such circuit expressions may be implemented include, but are not limited to, formats supporting behavioral languages such as C, Verilog, and VHDL, formats supporting register level description languages like RTL, and formats supporting geometry description languages such as GDSII, GDSIII, GDSIV, CIF, MEBES and any other suitable formats and languages. Computer-readable media in which such formatted data and/or instructions may be embodied include, but are not limited to, non-volatile storage media in various forms (e.g., optical, magnetic or semiconductor storage media) and carrier waves that may be used to transfer such formatted data and/or instructions through wireless, optical, or wired signaling media or any combination thereof. Examples of transfers of such formatted data and/or instructions by carrier waves include, but are not limited to, transfers (uploads, downloads, e-mail, etc.) over the Internet and/or other computer networks via one or more data transfer protocols (e.g., HTTP, FTP, SMTP, etc.).

When received within a computer system via one or more computer-readable media, such data and/or instruction-based expressions of the above described circuits may be processed by a processing entity (e.g., one or more processors) within the computer system in conjunction with execution of one or more other computer programs including, without limitation, net-list generation programs, place and route programs and the like, to generate a representation or image of a physical manifestation of such circuits. Such representation or image may thereafter be used in device fabrication, for example, by enabling generation of one or more masks that are used to form various components of the circuits in a device fabrication process.

In the foregoing description and in the accompanying drawings, specific terminology and drawing symbols have been set forth to provide a thorough understanding of embodiments of the invention. In some instances, the terminology and symbols may imply specific details that are not required to practice the invention. For example, any of the specific numbers of bits, signal path widths, signaling or operating frequencies, component circuits or devices and the like may be different from those described above in alternative embodiments. Also, the interconnection between circuit elements or circuit blocks shown or described as multi-conductor signal links may alternatively be single-conductor signal links, and single conductor signal links may alternatively be multi-conductor signal links. Signals and signaling paths shown or described as being single-ended may also be differential, and vice-versa. Similarly, signals described or depicted as having active-high or active-low logic levels may have opposite logic levels in alternative embodiments. Component circuitry within integrated circuit devices may be implemented using metal oxide semiconductor (MOS) technology, bipolar technology or any other technology in which logical and analog circuits may be implemented. With respect to terminology, a signal is said to be “asserted” when the signal is driven to a low or high logic state (or charged to a high logic state or discharged to a low logic state) to indicate a particular condition. Conversely, a signal is said to be “deasserted” to indicate that the signal is driven (or charged or discharged) to a state other than the asserted state (including a high or low logic state, or the floating state that may occur when the signal driving circuit is transitioned to a high impedance condition, such as an open drain or open collector condition). A signal driving circuit is said to “output” a signal to a signal receiving circuit when the signal driving circuit asserts (or deasserts, if explicitly stated or indicated by context) the signal on a signal line coupled between the signal driving and signal receiving circuits. A signal line is said to be “activated” when a signal is asserted on the signal line, and “deactivated” when the signal is deasserted. Additionally, the prefix symbol “/” attached to signal names indicates that the signal is an active low signal (i.e., the asserted state is a logic low state). A line over a signal name (e.g., ‘ <̅s̅i̅g̅n̅a̅l̅ n̅a̅m̅e̅>̅’) is also used to indicate an active low signal. The term “coupled” is used herein to express a direct connection as well as a connection through one or more intervening circuits or structures. Integrated circuit device “programming” may include, for example and without limitation, loading a control value into a register or other storage circuit within the device in response to a host instruction and thus controlling an operational aspect of the device, establishing a device configuration or controlling an operational aspect of the device through a one-time programming operation (e.g., blowing fuses within a configuration circuit during device production), and/or connecting one or more selected pins or other contact structures of the device to reference voltage lines (also referred to as strapping) to establish a particular device configuration or operation aspect of the device. The term “exemplary” is used to express an example, not a preference or requirement.

The section headings provided in this detailed description are for convenience of reference only, and in no way define, limit, construe or describe the scope or extent of such sections. Also, while the invention has been described with reference to specific embodiments thereof, it will be evident that various modifications and changes may be made thereto without departing from the broader spirit and scope of the invention. For example, features or aspects of any of the embodiments may be applied, at least where practicable, in combination with any other of the embodiments or in place of counterpart features or aspects thereof. Accordingly, the specification and drawings are to be regarded in an illustrative rather than a restrictive sense.

What is claimed is:

1. An integrated circuit (IC) device comprising:
structures that exhibit performance degradation as a function of use; and
heating circuitry disposed in proximity to the structures to heat the structures to a temperature that reverses the degradation.

2. The integrated circuit device of claim 1 further comprising a substrate, and wherein the structures that exhibit performance degradation comprise insulating elements within field-effect transistors fabricated at least in part within the substrate.

3. The integrated circuit device of claim 2 wherein the transistors include respective charge storage elements that are isolated from the substrate by the insulating elements.

4. The integrated circuit device of claim 2 wherein the insulating elements comprise oxides within a Flash memory cell.

5. The integrated circuit device of claim 1 wherein the structures comprise Flash memory cells.

6. The integrated circuit device of claim 1 wherein the heating circuitry comprises a heating element and a power delivery circuit to switchably enable current flow within the heating element.

7. The integrated circuit device of claim 6 wherein the structures comprise a plurality of Flash memory cells and wherein the heating element comprises a word line that forms a control gate for each of the Flash memory cells.

8. The integrated circuit device of claim 7 wherein the power delivery circuit comprises a first switch element to switchably couple a first end of the word line to a first voltage node and a second switch element to switchably couple a second end of the word line to a second voltage node, the first voltage node to be at a higher potential than the second voltage node during device operation such that a current is enabled to flow in a first direction through the word line to raise the temperature thereof.

9. The integrated circuit device of claim 8 further comprising circuitry to bias a bulk substrate of the integrated circuit device to a voltage level that prevents loss of data stored within the Flash memory cells during an interval in which the word line is switchably coupled between the first and second voltage nodes.

10. The integrated circuit device of claim 8 wherein the power delivery circuit comprises a third switch element to switchably couple the first end of the word line to the second voltage node and a fourth switch element to switchably couple the second end of the word line to the first voltage node such that a current is enabled to flow through the word line in a direction opposite the first direction.

11. The integrated circuit device of claim 8 further comprising a control circuit to switch the first and second switch elements to a conducting state during a first interval and to a non-conducting state during a second interval, the control circuit further to switch the third and fourth switch elements to the non-conducting state during the first interval and to the conducting state during the second interval.

12. The integrated circuit device of claim 5 wherein the structures comprise a plurality of storage cells and wherein the heating element comprises a word line coupled to the storage cells.

13. The integrated circuit device of claim 5 wherein the structures comprise a plurality of storage cells within a storage array and wherein the heating element comprises a bit line coupled to the storage cells to enable data transfer between the storage cells and circuitry external to the storage array.

14. The integrated circuit device of claim 5 wherein the structures comprise a plurality of transistors and wherein the heating element comprises a conductive element dedicated to heating the plurality of transistors at selected times.

15. The integrated circuit device of claim 1 further comprising a control circuit to enable the heating circuitry to heat the structures during a first interval and to disable the heating circuitry from heating the structures during a second interval.

16. The integrated circuit device of claim 15 wherein the control circuit outputs a temperature control signal to the heating circuitry to control the temperature to which the structures are heated.

17. The integrated circuit device of claim 16 wherein heating circuitry comprises a temperature sensing element to generate a signal indicative of the temperature to which the structures are heated, and wherein the control structure includes circuitry to adjust the temperature control signal according to whether signal indicate of the temperature indicates that the temperature is above or below a desired temperature.

18. The integrated circuit device of claim 16 wherein the control circuit receives a setpoint value that indicates a desired temperature and wherein the control circuit generates the temperature control signal based, at least in part, on the setpoint value.

19. The integrated circuit device of claim 1 further comprising a control circuit to determine whether a triggering threshold has been reached and to enable the heating circuitry to heat the structures in response to determining that the triggering threshold has been reached.

20. A method of operation within an integrated circuit device having structures that exhibit performance degradation as a function of use, the method comprising powering a heating element formed integrally with the integrated circuit device to heat the structures to a temperature that reverses the degradation.

21. The method of claim 20 wherein powering a heating element to heat the structures to a temperature that reverses the degradation comprises switchably coupling first and second ends of a word line to first and second voltage nodes to enable a current to flow through the word line and raise the temperature thereof, the word line forming the control gate of a plurality of non-volatile storage cells which constitute the structures to be heated.

22. The method of claim 20 wherein powering a heating element to heat the structures to a temperature that reverses the degradation comprises switchably coupling first and second ends of a bit line to first and second voltage nodes to enable a current to flow through the bit line and raise the temperature thereof, the bit line providing access to a plurality of non-volatile storage cells which constitute the structures to be heated.

23. The method of claim 20 wherein powering a heating element to heat the structures to a temperature that reverses the degradation comprises controlling the temperature in accordance with a setpoint value.

24. The method of claim 20 wherein powering a heating element to heat the structures to a temperature that reverses the degradation comprises receiving an indication of the temperature and adjusting power delivery to the heating element according to whether the indication of the temperature indicates a temperature above or below a desired temperature.

25. The method of claim 20 wherein powering a heating element comprises switchably coupling the heating element to a power source in response to determining that a threshold has been reached.

26. The method of claim 25 wherein switchably coupling the heating element to a power source in response to determining that a threshold has been reached comprises switchably coupling the heating element to the power source in response to determining that a predetermined amount of time has elapsed.

27. The method of claim 25 wherein switchably coupling the heating element to a power source in response to determining that a threshold has been reached comprises switchably coupling the heating element to the power source in response to determining that a predetermined number of performance-degrading operations have been performed within the integrated circuit device.

28. The method of claim 20 wherein powering a heating element comprises switchably coupling the heating element to a power source in response to detecting a condition that indicates a performance degradation.

29. The method of claim 28 wherein switchably coupling the heating element to a power source in response to detecting a condition that indicates a performance degradation comprises switchably coupling the heating element to a power source in response to detecting a threshold number of bit errors within a non-volatile storage array.

30. The method of claim 28 wherein switchably coupling the heating element to a power source in response to detecting a condition that indicates a performance degradation comprises switchably coupling the heating element to a power source in response to detecting that a number of program operations required to program data within a non-volatile storage cell has exceeded a predetermined threshold.

31. The method of claim 20 wherein powering a heating element comprises switchably coupling the heating element to a power source in response to detecting another operation is to be performed within the integrated circuit device.

32. The method of claim 31 wherein switchably coupling the heating element to a power source in response to detecting another operation is to be performed within the integrated circuit device comprises switchably coupling the heating element to a power source in response to a command to perform an erase operation within selected non-volatile storage cells of the integrated circuit device.

33. The method of claim 20 further comprising biasing a bulk substrate of the integrated circuit device to a voltage that prevents loss of data stored within non-volatile storage cells of the integrated circuit device while powering the heating element, wherein the non-volatile storage cells constitute the structures heated by the heating element.

34. An integrated circuit device comprising:
structures that exhibit performance degradation as a function of use; and
means for heating the structures to a temperature that reverses the degradation.

35. A manufacture comprising one or more computer-readable media, the computer-readable media having information embodied therein that describes a physical implementation of an integrated circuit device, the information including descriptions of:
structures formed integrally with the integrated circuit device that exhibit performance degradation as a function of use; and
heating circuitry formed integrally with the integrated circuit device and disposed in proximity to the structures to heat the structures to a temperature that reverses the degradation
